(19) United States
(12) Patent Application Publication
(10) Pub. No.: US 2005/0133907 A1
(43) Pub. Date: Jun. 23, 2005

(54) Mechanism for maintaining consistent thermal interface layer in an integrated circuit assembly

(76) Inventors: Thomas Richard Hildner, Apex, NC (US); Vinod Kamath, Raleigh, NC (US)

Correspondence Address: LALLY & LALLY, L.L.P., P. O. BOX 684749, AUSTIN, TX, 78768-4749, US

(21) Appl. No.: 10/744,835

(22) Filed: Dec. 23, 2003

(51) Int. Cl. H01L 23/34

(52) U.S. Cl. 257/717

(57) ABSTRACT

An integrated circuit assembly includes an integrated circuit overlying a printed circuit board and a thermal solution interface such as a fan sink or a heat pipe overlying the integrated circuit. The lower surface of the thermal solution interface has a plurality of spacer structures to enforce a uniform displacement between the lower surface and an underlying surface contacted by the spacers. A heat transfer material, such as a thermal phase change material or a thermal grease, is positioned between the thermal solution interface and the underlying surface contacted by the spacers. The assembly may include a socket connected to the printed circuit board into which the integrated circuit is inserted. The spacers likely enforce a uniform displacement in the range of approximately 0.001 to 0.005 inches. The spacers may be configured as a set of substantially hemispherical protrusions or a set of substantially parallel elongated ridge protrusions.

### BACKGROUND

1. Field of the Present Invention

The present invention is in the field of integrated circuits and, more particularly to integrated circuits that use heat dissipation hardware.

2. History of Related Art

Mobile processors including notebook and desktop computers have historically used a thermal interface pad to participate in the heat transfer process. Thermal interface pads are characterized by a one-sided adhesive, which makes it relatively easy to apply and to remove the thermal solution. A drawback is that the thermal interface pad has poor thermal conductivity. As the maximum designed thermal power of CPUs has increased, this pad has proven to be insufficient for most applications.

The inadequacy of thermal interface pads as a heat transfer mechanism forced mobile processing device manufacturers to employ thermal greases or “phase change” materials that had been in use on desktops machines and server-class computers for some time. Standard phase change materials are typically a polymer/carrier filled with a thermally conductive filler, which changes from a solid to a high-viscosity liquid (or semi-solid) state at a certain transition temperature typically in the range of 50 to 70° C. These materials conform well to irregular surfaces and have wetting properties similar to thermal greases, which significantly reduces the contact resistance at the different interfaces. Due to this composite structure, phase change materials are able to withstand mechanical forces during shock and vibration, protecting the die or component from mechanical damage. When heated to the transition temperature, the material significantly softens to a near liquid-like physical state in which the thermally conductive material slightly expands in volume. This volumetric expansion forces the more thermally conductive material to flow into and replace the microscopic air gaps present in between the heat sink and electronic component. With the air gaps filled between the thermal surfaces, a high degree of wetting of the two surfaces minimizes the contact resistance.

Unfortunately, phase change materials and thermal greases are difficult to use in a manufacturing environment. Specifically, the quasi-liquid characteristics of phase change materials and thermal greases are sensitive to any gradient in the pressure applied to the film. Typically, the phase change material is situated between a thermal interface such as the bottom of a heat sink, a fan sink assembly, a vapor chamber, or a heat spreader (with or without heat pipes) surface and an upper surface of the device itself. In either case, maintaining a uniformly thick film is important and difficult. It is important to ensure the best heat transfer characteristics possible and thereby improve device performance, reliability, and lifetime. It would be desirable, therefore, to implement an integrated circuit assembly that permitted the use of these advanced heat transfer materials and addressed the difficulty of maintaining a uniform thickness inherent with these materials.

### SUMMARY OF THE INVENTION

The objective identified above is achieved according to the present invention by an integrated circuit assembly that includes an integrated circuit overlying a printed circuit board and a thermal solution interface such as a fan sink or a heat pipe overlying the integrated circuit. The lower surface of the thermal solution interface has a plurality of spacer structures to enforce a uniform displacement between the lower surface and an underlying surface contacted by the spacers. A heat transfer material, such as a thermal phase change material or a thermal grease, is positioned between the thermal solution interface and the underlying surface contacted by the spacers. The assembly may include a socket connected to the printed circuit board into which the integrated circuit is inserted. The integrated circuit may include a thermally conductive heat spreader attached to its upper surface such that the spacers contact an upper surface of the heat spreader. In other embodiments, the heat transfer material directly contacts an upper surface of the integrated circuit die. The spacers likely enforce a uniform displacement in the range of approximately 0.001 to 0.005 (dependent on ideal properties of the interface material) inches. The spacers may be configured as a set of substantially hemispherical protrusions or a set of substantially parallel elongated ridge protrusions.

### BRIEF DESCRIPTION OF THE DRAWINGS

Other objects and advantages of the invention will become apparent upon reading the following detailed description and upon reference to the accompanying drawings in which:

FIG. 1 is a diagram of an integrated circuit assembly according to one embodiment of the invention emphasizing a thermal interface having a set of spacer structures;

FIG. 2 is a bottom view of one embodiment of the thermal interface of FIG. 1;

FIG. 3 is a bottom view of an alternative embodiment of the thermal interface of FIG. 1;

FIG. 4 is a diagram of an alternative implementation of the integrated circuit assembly of FIG. 1;

FIG. 5 is a diagram of an alternative implementation of the integrated circuit assembly of FIG. 1; and

FIG. 6 is a diagram of an alternative embodiment of the integrated circuit assembly of FIG. 1.

While the invention is susceptible to various modifications and alternative forms, specific embodiments thereof are shown by way of example in the drawings and will herein be described in detail. It should be understood, however, that the drawings and detailed description presented herein are not intended to limit the invention to the particular embodiment disclosed, but on the contrary, the intention is to cover all modifications, equivalents, and alternatives falling within the spirit and scope of the present invention as defined by the appended claims.

### DETAILED DESCRIPTION OF THE INVENTION

Generally speaking, the present invention is concerned with an integrated circuit assembly that employs semi-liquid heat transfer materials such as thermal grease and/or phase change materials. The semi-liquid material is formed between a pair of surfaces of the assembly. At least one of the surfaces includes spacer structures formed thereon. The spacer structures are preferably of a uniform dimension and, in one embodiment, are hemispherical. The presence of the spacer structures positioned across the face of the surface enforces a uniform separation between the two plates between which the phase change material is present. Any gradient in pressure across the face of the surface will not result in a heat transfer material thickness gradient or non-uniformity. By maintaining a uniformly thick phase change material across a heat transfer interface of an integrated circuit, the invention beneficially improves the heat transfer properties of the integrated circuit by eliminating localized “hot spots” that may occur when portions of the heat transfer material are thinner than others.

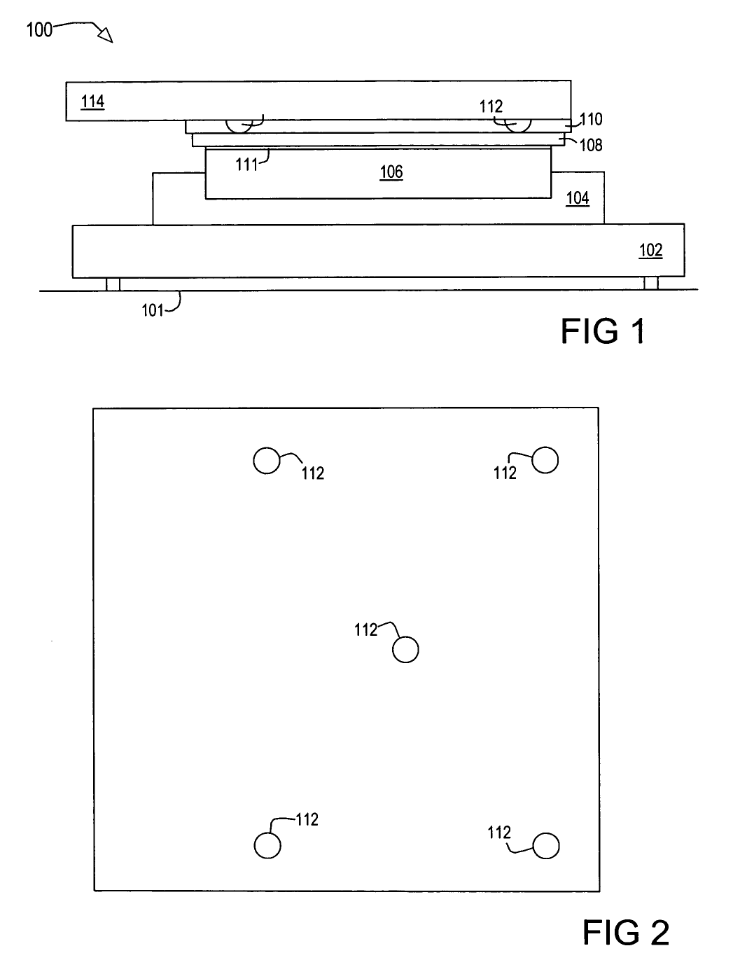

Turning now to the drawings, FIG. 1 is a plan view of an integrated circuit assembly 100 according to one embodiment of the invention for use with a data processing system. In the depicted embodiment, which is likely implemented in conjunction with a desktop or server-class data processing system, assembly 100 includes a printed a socket 104 overlying a printed circuit board 102. Printed circuit board 102, which is connected to a chassis 101 of the system, is exemplified by the system's motherboard in a desktop PC implementation or a processor planer in a server class machine. An integrated circuit 106 is positioned with the socket 104. Integrated circuit 106 may be any integrated circuit that employs active or passive heat transfer hardware. In a likely embodiment, integrated circuit 106 is a general purpose microprocessor or central processing unit (CPU) such as PowerPC® family of processors from IBM Corporation or an x86 family processor. CPU's represent the integrated circuits most likely to employ heat transfer hardware because of the amount of heat such devices generate. Increasingly, however, other integrated circuits including graphics controllers, chipsets, memory devices, and other integrated circuits are employing heat transfer mechanisms to combat the ever increasing performance demands. Integrated circuit 106 may be a packaged device in which the integrated circuit die is located within a plastic or ceramic package. Alternatively, integrated circuit 106 may comprise an un-packaged die inserted into socket 104.

A heat spreader 108 is shown as attached to an upper surface of integrated circuit 106. Heat spreader 108 (also referred to as an integrated circuit cap) is preferably a thermally conductive material that facilitates the transfer of heat from integrated circuit 106. A preferred implementation of heat spreader 108 is made of copper. A thermal paste or grease 111 is likely placed between heat spreader 108 and an upper surface of integrated circuit 106 to further enhance the efficiency of heat transfer.

A thermal solution interface 114 is shown as resting on an upper surface of heat spreader 108. Interface 114 may comprise the lower portion of a heat sink or fan sink assembly that is attached to printed circuit board 102. In the preferred implementation, thermal interface 114 is secured from above using a spring force (not shown) or other securing mechanism (such as a set of screws), to maintain the thermal interface in proximity to the underlying integrated circuit 106.

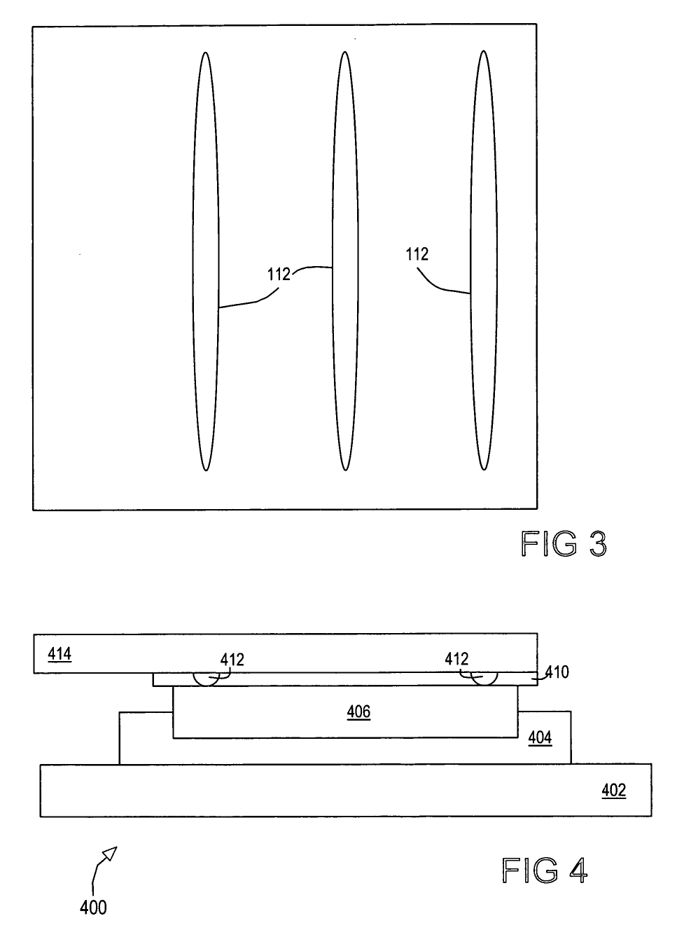

In the depicted embodiment, thermal solution interface includes a plurality of spacers 112 formed on the surface of interface 114. As depicted in the bottom view of FIG. 2, spacers 112 are uniformly dimensioned, hemispherical structures that protrude from the surface of thermal solution interface 114. The depicted implementation of spacers 112 includes a spacer 112 positioned to contact heat spreader 108 at each corner of the die and a fifth spacer centered among the other four, but this pattern is implementation specific and other patterns of spacers 112 are within the scope of the invention. In applications requiring a larger surface area or higher pressure, as examples, the number of spacers may be increased. In the embodiment depicted in FIG. 3, spacers 112 are implemented as a set of three evenly spaced, elongated ridged protrusions. In either embodiment, the uniform dimension of the spacers enforces a uniform separation between the surface of interface 114 and the upper surface of heat spreader 108. In one embodiment, spacers 112 are formed from (i.e., are integral with) thermal solution interface 114 so that spacers 112 have the same composition as interface 114. Spacers 112 may be formed by any of a variety of methods including milling, stamping, and chemical etching. The critical dimension of spacers 112 is the amount of displacement that spacers 112 enforce between thermal interface 114 and the surface that spacers 112 contact. In a likely integrated circuit application, this dimension is in the range of 1 to 5 mils (thousandths of an inch).

Returning to FIG. 1, a heat transfer material 110 is applied between thermal solution interface 114 and heat spreader 108. The heat transfer material 110 is preferably a thermal phase change material or a thermal grease. Thermal phase change materials are exemplified by the Hi-Flow® family of phase change materials from the Bergquist Company. Thermal greases suitable for use in assembly 100 include the Cooler Master thermal compound from Shin Etsu Chemical Company. In any of these embodiments, heat transfer material 110 may exhibit liquid or quasi-liquid properties at certain temperatures. Specifically, the heat transfer material may be unable to withstand a pressure gradient without conforming or yielding to the pressure-applying surface. When this is the case, maintaining a uniformly thick heat transfer material is difficult in the absence of spacers 112.

Referring to FIG. 6, an alternative embodiment of system 100 extends the spacer concept by incorporating spacers 109 affixed to a lower surface of heat spreader 108 and introducing a heat transfer material 107 between heat spreader 108 and CPU die 106. Like heat transfer material 110, heat transfer material 107 may include a thermal phase change material or a thermal grease.

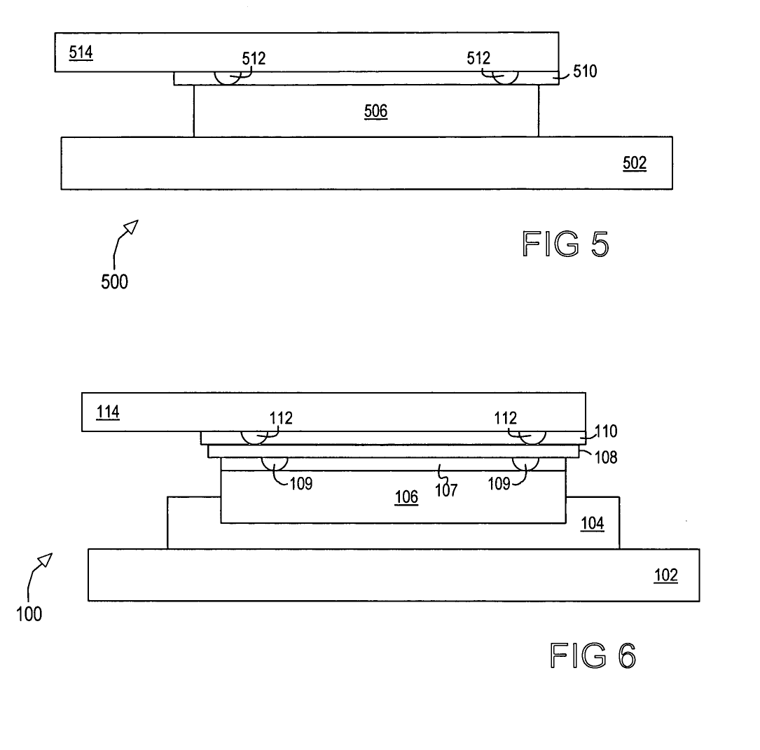

The embodiment of assembly 100 depicted in FIG. 1, is characteristic of a desktop or server application in which a heat spreader or thermal cap 108 covers the CPU die 106. Referring now to FIG. 4 and FIG. 5, alternative embodiments of integrated circuit assemblies according to the present invention are depicted to emphasize applications more suitable for mobile computing applications that require lower profile assemblies. In FIG. 4, an integrated circuit assembly 400 includes a socket 404 overlying a printed circuit board 402. An integrated circuit die 406 is positioned within socket 404. Heat transfer material 410, which is analogous to heat transfer material 110 of FIG. 1, is located between a thermal solution interface 414 and an upper surface of integrated circuit die 406. Thermal solution interface 414 includes spacers 412 that are equivalent to the spacers 112 of FIG. 1. In this application, spacers 412 and heat transfer material 410 are in direct contact with the upper surface of integrated circuit die 406. This embodiment achieves a slightly reduced profile while still employing a socket 404 that enables customers to replace the socketed device (integrated circuit die 406).

An even lower profile is achieved with the integrated circuit assembly 500 depicted in FIG. 5. In this implementation, the integrated circuit die 506 is connected (soldered) directly to the underlying printed circuit board 502. The thermal solution interface 514 includes spacers 512, equivalent to the spacers 112 of FIG. 1 and 412 of FIG. 4, that contact an upper surface of integrated circuit die 506. The heat transfer material 510, analogous to materials 110 and 410, is located between thermal solution interface 514 and integrated circuit die 506.

It will be apparent to those skilled in the art having the benefit of this disclosure that the present invention contemplates a mechanism for maintaining a uniform dimension of a thermal interface material in an integrated circuit assembly. It is understood that the forms of the invention shown and described in the detailed description and the drawings are to be taken merely as presently preferred examples. It is intended that the following claims be interpreted broadly to embrace all the variations of the preferred embodiments disclosed.

1. An integrated circuit assembly, comprising:
an integrated circuit overlying a printed circuit board;
a thermal solution interface overlying the integrated circuit, the thermal solution interface comprising a lower surface including a plurality of spacer structures to enforce a uniform displacement between the lower surface and an underlying surface contacted by the spacers; and
a heat transfer material between the thermal solution interface and the underlying surface contacted by the spacers.

2. The assembly of claim 1, wherein the heat transfer material comprises a thermal phase change material.

3. The assembly of claim 1, wherein the assembly further includes a socket connected to the printed circuit board, wherein the integrated circuit is inserted within the socket.

4. The assembly of claim 3, wherein the integrated circuit includes a thermally conductive heat spreader attached to an upper surface of the integrated circuit, wherein the spacers contact an upper surface of the heat spreader.

5. The assembly of claim 1, wherein the spacers and the heat transfer material directly contact an upper surface of the integrated circuit die.

6. The assembly of claim 1, wherein the spacers enforce a uniform displacement in the range of approximately 0.001 to 0.005 inches.

7. The assembly of claim 1, wherein the spacers comprise a set of substantially hemispherical protrusions.

8. The assembly of claim 7, wherein the set of spacers is configured with a spacer positioned to contact each corner of the underlying surface and a spacer in the center thereof.

9. The assembly of claim 1, wherein the spacers comprise a set of substantially parallel elongated ridge protrusions.

10. A thermal solution interface for contacting an upper surface of an integrated circuit, wherein the lower surface of the interface includes a plurality of spacer structures to maintain the lower surface of the interface at a uniform displacement from the upper surface of the integrated circuit when the interface contacts the integrated circuit.

11. The thermal solution interface of claim 10, wherein the spacers enforce a uniform displacement in the range of approximately 0.001 to 0.005 inches.

12. The thermal solution interface of claim 10, wherein the spacers comprise a set of substantially hemispherical protrusions.

13. The thermal solution interface of claim 12, wherein the set of spacers is configured with a spacer positioned to contact each corner of the underlying surface and a spacer in the center thereof.

14. The thermal solution interface of claim 10, wherein the spacers comprise a set of substantially parallel elongated ridge protrusions.

15. A data processing system, comprising:
a chassis and a printed circuit board connected to the chassis;
an integrated circuit overlying the printed circuit board;
a thermal solution interface overlying the integrated circuit, the thermal solution interface comprising a lower surface including a plurality of spacer structures to enforce a uniform displacement between the lower surface and an underlying surface contacted by the spacers; and
a heat transfer material between the thermal solution interface and the underlying surface contacted by the spacers.

16. The data processing system of claim 15, wherein the assembly further includes a socket connected to the printed circuit board, wherein the integrated circuit is inserted within the socket.

17. The data processing system of claim 16, wherein the integrated circuit includes a thermally conductive heat spreader attached to an upper surface of the integrated circuit, wherein the spacers contact an upper surface of the heat spreader.

18. The data processing system of claim 15, wherein the spacers and the heat transfer material directly contact an upper surface of the integrated circuit die.

19. The data processing system of claim 15, wherein the spacers comprise a set of substantially hemispherical protrusions.

20. The data processing system of claim 15, wherein the spacers comprise a set of substantially parallel elongated ridge protrusions.
